(19) United States
(12) Patent Application Publication
(10) Pub. No.: US 2004/0106291 A1
(43) Pub. Date: Jun. 3, 2004

(54) Thermally enhanced wafer-level chip scale package and method of fabricating the same

(75) Inventors: Tzong Da Ho, Taichung (TW); Chien Ping Huang, Hsinchu (TW)

Correspondence Address: EDWARDS & ANGELL, LLP, P.O. Box 9169, Boston, MA, 02209, US

(73) Assignee: Siliconware Precision Industries Co., Ltd.

(21) Appl. No.: 10/719,912

(22) Filed: Nov. 21, 2003

Related U.S. Application Data
(62) Division of application No. 09/848,137, filed on May 3, 2001, now abandoned.

(51) Int. Cl. H01L 21/302; H01L 21/461

(52) U.S. Cl. 438/689

(57) ABSTRACT

A thermally-enhanced wafer-level chip scale package (WLCSP) and method of fabricating the same is proposed, which allows easy integration of a thermally-conductive stiffener to each package unit fabricated through the WLCSP technology. The proposed WLCSP technology is characterized by the attachment of a thermally-conductive stiffener to the back side of the semiconductor wafer, which is subsequently cut during the singulation process into separate pieces respectively attached on each of the singulated integrated circuit chips from the semiconductor wafer. The thermally-conductive stiffener riot only serves as a heat-dissipation means for each chip during operation, but also serves to reinforce the chip so that the chip can be protected against cracking or chipping during flip-chip die bonding process or during handling and transportation.

### BACKGROUND OF THE INVENTION

1. Field of the Invention

This invention relates to semiconductor packaging technology, and more particularly, to a thermally-enhanced wafer-level chip scale package (WLCSP) and method of fabricating the same, which allows easy integration of a thermally-conductive stiffener to each package unit fabricated-through the WLCSP technology.

2. Description of Related Art

WLCSP (Wafer-Level Chip Scale Package) is an advanced type of semiconductor packaging technology that allows the overall package size to be made very small to the level of the wafer thickness and chip area. The WLCSP type of semiconductor packages can achieve this small size due to the use of flip chip technology, in which the packaged chip is mounted in an upside-down manner over a circuited substrate and bonded to the same by means of solder bumps. The flip chip technology is well-known in the semiconductor industry, so description thereof will not be further detailed.

A few of the patents related to WLCSP technologies are listed in the following:

U.S. Pat. No. 6,103,552 “WAFER SCALE PAKCAGING SCHEME”;

U.S. Pat. No. 6,011,314 “REDISTRIBUTION LAYER AND UNDER BUMP MATEERIAL STRUCUTRE FOR CONVERTING PERIPHERY CONDUCTIVE PADS TO AN ARRAY OF SOLDER BUMPS”.

U.S. Pat. No. 5,902,686 “METHODS FOR FORMING AN INTERMEALLIC REGION BETWEEN A SOLDER BUMP AND AN UNDER BUMP METALLURGY LAYER AND RELATED STRUCUTRES”;

U.S. Pat. No. 5,851,911 “MASK REPATTERN PROCESS”; and

U.S. Pat. No. 5,450,283 “THERMALLY ENHANCED SEMICONDUCTOR DEVICE HAVING EPOXED BACKSIDE AND METHOD FOR MAKING THE SAME”.

The U.S. Pat. No. 6,103,552 discloses a process and a package for achieving wafer scale packaging. The U.S. Pat. No. 5,450,283 discloses a thermally enhanced semi-conductor device having an exposed backside, which is bonded to the substrate through FCBGA (Flip Chip Ball Grid Array) technology. The U.S. Pat. Nos. 6,011,314, No. 5,902,686, and No. 5,851,911 disclose new RDL (Redistribution Layer) technologies that are used to redistribute peripheral I/O points to predefined array locations to facilitate the bonding of solder bumps in the bumping process.

Conventional WLCSP technologies, however, have the following drawbacks.

First, heat-dissipation means is externally coupled to each individual package unit, which would make the overall packaging process highly laborious and time consuming and thus costly to implement.

Second, since a raw wafer is relative large in thickness, typically from 25 mil to 30 mil, it has to undergo a lapping process to grind away a back-side portion thereof so as to make the wafer thinner, typically down to 6 mil to 10 mil in thickness. The thinned wafer allows the final package size to be made more compact. One drawback to the thinned wafer, however, is that it would make the singulated chip easily subjected to cracking or chipping during the flip-chip die bonding process.

Third, since the packaged chip in WLCSP package is exposed without encapsulation, it would be easily subjected to cracking or chipping by external force during handling and transportation.

Fourth, since the packaged chip in WLCSP package is exposed without encapsulation, product serial number or identification marks should be directly imprinted on the back-side of the packaged chip, typically through the use of laser imprinting means. One draw-back to the use of laser imprinting means, however, is that it is quite costly to use. Moreover, the laser imprinted marks are considered quite poor in visibility.

### SUMMARY OF THE INVENTION

It is therefore an objective of this invention to provide a new WLCSP technology that allows easier coupling of thermally-conductive means to each of the chips in a semiconductor wafer.

It is another objective of this invention to provide a new WLCSP technology that allows reinforcement to the thinned wafer so as to prevent the chips singulated from the wafer against cracking or chipping during the flip-chip die bonding process.

It is still another objective of this invention to provide a new WLCSP technology that can prevent the packaged chip from being cracked or chipped by external force during handing or transportation.

It is yet another objective of this invention to provide a new WLCSP technology that allows easy imprinting of product serial numbers or identification marks on each finished package unit without having to use laser imprinting means.

In accordance with the foregoing and other objectives, the invention proposes a new WLCSP technology for fabrication of thermally-enhanced WLCSP packages.

The WLCSP technology according to the invention comprises the following steps: (1) preparing a semiconductor wafer having a front side and a back side, and which is predefined into a plurality of-integrated circuit chips; (2) performing a bumping process to bond a plurality of solder bumps on the front side of the semiconductor wafer, (3) performing a back-side lapping process to grind away a back-side portion of the semiconductor wafer, (4) attaching a thermally-conductive stiffener to the back side of the semiconductor wafer, (5) performing a singulation process to cut apart each chip from the semiconductor wafer, and (6) performing a flip-chip die bonding process to mount each singulated chip by means of the solder bumps onto a circuited substrate.

The WLCSP technology according to the invention is characterized by the attachment of the thermally-conductive stiffener to the back side of the semiconductor wafer, which is subsequently cut during the singulation process into separate pieces respectively attached on each of the singulated integrated circuit chips. The thermally-conductive stiffener not only serves as a heat-dissipation means for each chip during operation, but also serves to reinforce the chip so that the chip can be protected against cracking or chipping during flip-chip die bonding process or during handling and transportation.

### BRIEF DESCRIPTION OF DRAWINGS

The invention can be more fully understood by reading the following detailed description of the preferred embodiments, with reference made to the accompanying drawings, wherein:

FIG. 1 is a schematic sectional diagram showing a semiconductor wafer predefined into a plurality of chips;

FIG. 2 is a schematic sectional diagram showing the implementation of a bumping process on the semiconductor wafer of FIG. 1;

FIG. 3 is a schematic sectional diagram showing the implementation of a back-side lapping process on the semiconductor wafer of FIG. 2;

FIG. 4 is a schematic sectional diagram showing the attachment of implementation of a thermally-conductive stiffener on the semiconductor wafer of FIG. 3;

FIG. 5 is a schematic sectional diagram showing the implementation of a singulation process on the semiconductor wafer of FIG. 4;

FIG. 6 is a schematic sectional diagram showing the implementation of a flip-chip die bonding process for each singulated chip from the semiconductor wafer of FIG. 5; and

FIG. 7 is a schematic sectional diagram showing a finished package unit fabricated through the WLCSP technology according to the invention.

### DETAILED DESCRIPTION OF PREFERRED EMBODIMENTS

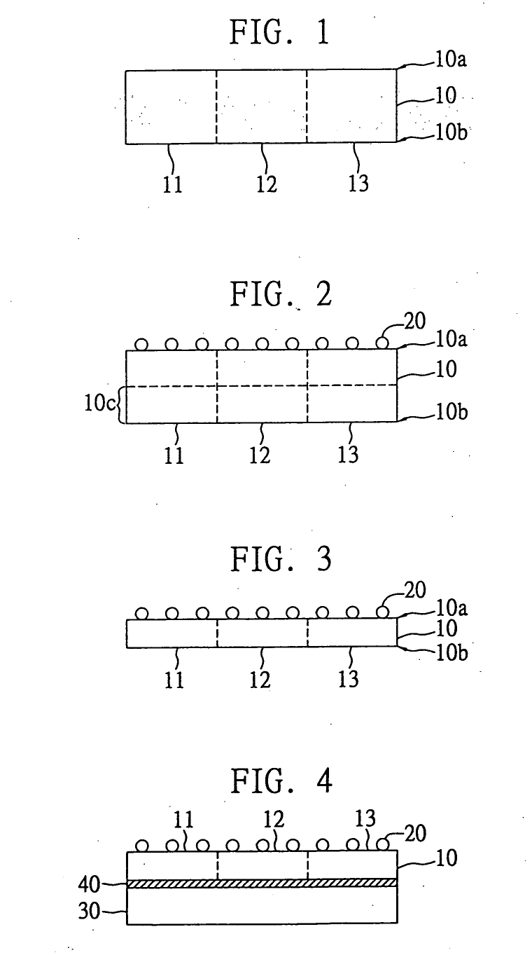

A preferred embodiment of the WLCSP technology according to the invention is disclosed in full details in the following with reference to FIG. 1 through FIG. 7.

Referring to FIG. 1, by the WLCSP technology according to the invention, the first step is to prepare a semiconductor wafer 10 having a front side 10a and a back side 10b, and which is predefined into a plurality of regions, each being used for the fabrication of one single integrated circuit chip (for simplification of the drawings, only three chips are demonstratively illustrated, respectively labeled with the reference numerals 11, 12, 13). The front side 10a defines the active surfaces of the integrated circuit chips 11, 12, 13, while the back side 10b defines the inactive surfaces of the same.

Referring further to FIG. 2, in the next step, a bumping process is performed to bond an array of solder bumps 20 on the front side 10a of the semiconductor wafer 10 (i.e., the active surfaces of the integrated circuit chips 11, 12, 13). The bumping process is a conventional technique, so detailed steps thereof will not be further described.

Referring further to FIG. 3, in the next step, a back-side lapping process is performed to grind away a back-side portion 10c of the semiconductor wafer 10. This allows the semiconductor wafer 10, whose raw thickness is typically from 25 mil to 30 mil, to be thinned down to about from 6 mil to 10 mil in thickness. The thinned wafer 10 allows the final package size to be made more compact in thickness.

Referring further to FIG. 4, in the next step, a thermally-conductive stiffener 30, which is made of a thermally-conductive and rigid material such as copper or copper alloy, is adhered to the back side 10b of the semiconductor wafer 10 by means of a thermally-conductive adhesive layer 40, such as silver epoxy.

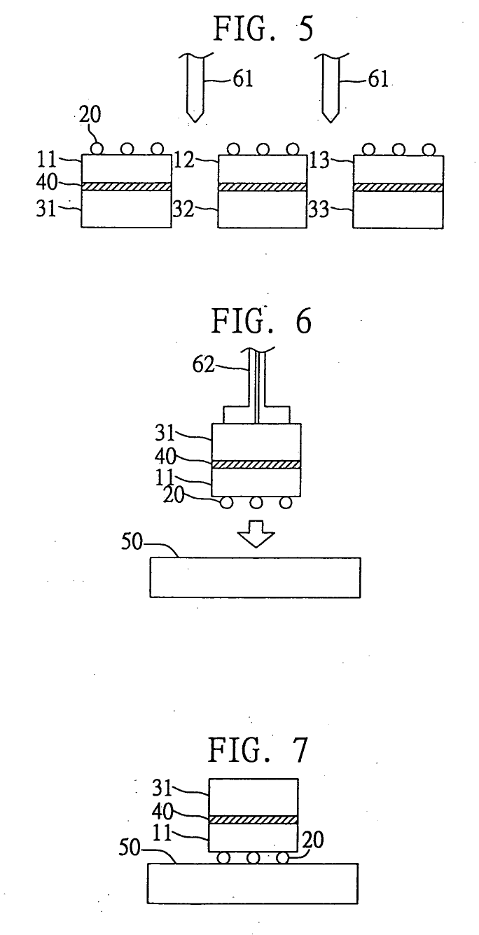

Referring further to FIG. 5, in the next step, a singulation process is performed through the use of a sawing tool 61 to cut each of the integrated circuit chips 11, 12, 13 apart from the semiconductor wafer 10. Through this singulation process, the thermally-conductive stiffener 30 is also cut into separate pieces 31, 32, 33, respectively attached on each of the singulated chips 11, 12, 13.

Referring further to FIG. 6, in the next-step, a flip-chip die bonding process is performed through the use of a pickup head 62 to pick and mount each of the singulated chips 11, 12, 13 (only the chip 11 is shown in FIG. 6) in an upside-down manner onto a circuited substrate 50. The chip 11 is then mechanically bonded and electrically coupled to the circuited substrate 50 by means of the solder bumps 20.

During the foregoing process, since the chip 11 is attached with a piece of thermally-conductive stiffener 31, it can be protected against cracking or chipping while being mounted forcefully by the pickup head 62 onto the circuited substrate 50.

FIG. 7 shows the finished package unit fabricated through the steps depicted in FIG. 1 through FIG. 6 according to the invention. During operation of the electronic device of this package unit, the thermally-conductive stiffener 31 serves as a heat-dissipation means for the packaged chip 11, so that the overall heat-dissipation efficiency can be enhanced.

Compared to the prior art, the WLCSP technology according to the invention has the following advantages.

First, the thermally-conductive stiffener 30 is attached to the semiconductor wafer 10 and then cut into separate pieces 31, 32, 33 along with the associated chips 11, 12, 13 during the singulation process, which is considerably much more convenient to implement than the conventional method of attaching a small piece of thermally-conductive stiffener to each of the singulated chips.

Second, owing to the provision of the thermally-conductive stiffener 30, the singulated chips 11, 12, 13 can be protected against cracking or chipping while being mounted onto a circuited substrate during the flip-chip die bonding process.

Third, owing to the provision of the thermally-conductive stiffener 30, the packaged chips 11, 12, 13 can be protected against cracking or chipping during handling or transportation.

Fourth, the required product serial numbers or identification marks can be pre-molded on the thermally-conductive stiffener 30, which is considerably easier and more cost-effective to implement than the use of laser imprinting means by prior art.

The invention has been described using exemplary preferred embodiments. However, it is to be understood that the scope of the invention is not limited to the disclosed embodiments. On the contrary, it is intended to cover various modifications and similar arrangements. The scope of the claims, therefore, should be accorded the broadest interpretation so as to encompass all such modifications and similar arrangements.

What is claimed is:

1. A method for fabricating a thermally-enhanced wafer-level chip scale package, comprising the steps of:
(1) preparing a semiconductor wafer having a front side and a back side, and which is predefined into a plurality of integrated circuit chips;
(2) performing a bumping process to bond a plurality of solder bumps on the front side of the semiconductor wafer,
(3) performing a back-side lapping process to grind away a back-side portion of the semiconductor wafer,
(4) attaching a thermally-conductive stiffener to the back side of the semiconductor wafer,
(5) performing a singulation process to cut apart each chip from the semiconductor wafer, and
(6) performing a flip-chip die bonding process to mount each singulated chip by means of the solder bumps onto a circuited substrate.

2. The method of claim 1, wherein in said step (4), the thermally-conductive stiffener is attached by means of silver epoxy to the semiconductor wafer.

3. The method of claim 1, wherein in said step (4), the thermally-conductive stiffener is made of copper.

4. The method of claim 1, wherein in said step (4), the thermally-conductive stiffener is made of a copper alloy.

5. A wafer-level chip scale package, which comprises:
(a) a circuited substrate;
(b) a semiconductor chip having an active surface and an inactive surface;
(c) a plurality of solder bumps bonded on the active surface of the semiconductor chip for bonding the semiconductor chip to the circuited substrate through flip-chip technology; and
(d) a thermally-conductive stiffener adhered to the inactive surface of the semiconductor chip.

6. The wafer-level chip scale package of claim 5, wherein the thermally-conductive stiffener is attached by means of silver epoxy to the semiconductor wafer.

7. The wafer-level chip scale package of claim 5, wherein the thermally-conductive stiffener is made of copper.

8. The wafer-level chip scale package of claim 5, wherein the thermally-conductive stiffener is made of a copper alloy.
